(19) United States
(12) Patent Application Publication
(10) Pub. No.: US 2011/0232737 A1
(43) Pub. Date: Sep. 29, 2011

(54) MULTILAYER SOLAR ELEMENT

(75) Inventors: Holger Ruletzki, Schoenfliess (DE); Holger Teich, Bernau (DE)

(73) Assignee: PARABEL AG, BERLIN (DE)

(21) Appl. No.: 12/745,579

(22) PCT Filed: Dec. 4, 2008
(86) PCT No.: PCT/EP08/66795

§ 371 Date: Sep. 13, 2010

(30) Foreign Application Priority Data
Dec. 4, 2007 (DE) 102007058750.5
Dec. 4, 2007 (DE) 202007017031.9

(51) Int. Cl. H01L 31/0216; B05D 5/12

(52) U.S. Cl. 136/256; 427/74

(57) ABSTRACT

The invention relates to a multilayer solar element (S), which includes a first layer (1) of a photovoltaic thin-film laminate which is coated on its bottom side as a bonding layer to a base or to a support material over its full surface area with a self-adhesive second layer (2) or a non-self-adhesive second layer (2′), or over part of its surface area with a self-adhesive second layer (2) or a non-self-adhesive second layer (2′) by adhesively bonding a self-adhesive or non-self-adhesive polymer-modified bitumen.

This application is a 371 application of PCT/EP2008/066795 filed Dec. 4, 2008, which claims priority to the German application 10 2007 058 750.5 filed Dec. 4, 2007 and German application 20 2007 017 031.9 filed Dec. 4, 2007.

The invention relates to a multilayer solar element, use of polymer-modified bitumen for coating the multilayer solar element, and an associated fabrication process with the associated apparatus.

DE 38 54 773 T2 discloses a conventional solar material made of thin-film barrier layer photo-structures or photovoltaic structures, which are formed of one or several stacked solar cells and which are electrically and optically connected in series. An intrinsic layer formed of the solar cells is “spatially stepped” across a significant portion of the bulk thickness, wherein this stepped portion is distant from the boundary surfaces between the intrinsic layer and a dopant layer so as to improve the open circuit voltage and/or the fill density.

This solar material is also referred to as a photovoltaic thin layer laminate and can be provided, for example, on the backside with an adhesive, on which subsequently an additional layer, mostly a flexible EPDM layer or a flexible sheet metal can be deposited. Because the thin layer laminate, the adhesive and the EPDM layer or the sheet-metal are still flexible solar modules in spite of their multilayer construction, so-called “flexible solar modules” are thereby obtained which can be adhesively bonded on different bases of roofs, similar to roof sheeting.

The photovoltaic thin layer laminate can also be adhesively bonded to a solid rigid support, yielding rigid, inflexible solar modules (so-called “solar panels”) which can be mechanically attached or less frequently also adhesively bonded to roof surfaces.

A butyl adhesive is used for producing both flexible and rigid solar modules. Disadvantageously, this butyl adhesive has in particular an insufficient peeling resistance (N/mm), which is a material property representing a subtype of bonding strength. It has been observed that the flexible and rigid solar modules produced with butyl adhesive, in particular after installation on a sloped roof, tend to “flow”. The bonding strength, in particular in conjunction with the heat introduced by the sun, is insufficient to permanently secure the adhesive joint of the flexible and rigid solar modules produced with butyl adhesive.

The bonding strength was determined in peeling tests as the quotient of the work w required to separate a strip (solar material) of length l and width b from the base material (EPDM layer) and the generated parting plane A.

Starting from this problem, an approach for a new solution was explored which obviates these disadvantages and provides increased shear strength and peeling resistance of the product.

Sealing strips are known in sealing technology from the laid-open patent application DE 199 10 420 A1 and the utility model DE 201 11 595 U1. The sealing strip in the laid-open patent application DE 199 10 420 A1 has on the bottom side of the sealing strip a self-adhesive bitumen coating. In the utility model DE 201 11 595 U1, both a top layer and a bottom layer are coated with the same bitumen adhesive as in DE 199 10 420 A1.

The sealing strips are partially self-adhesive and are suitable for installation on different bases, for example concrete, poured asphalt, bitumen, sheet metal and plastic roof sheeting.

Starting from the state-of-the-art, it was an object to provide solar elements which have a higher shear and peeling strength in practical applications, in particular when installed on sloped roofs, than conventional solar elements.

This object is attained in conjunction with the features of the preamble of claim 1, in that a multilayer solar element is deformed, which has a first layer of a photovoltaic thin-film laminate which is coated on its bottom side as a bonding layer to a base or to a support material over its full surface area with a self-adhesive second layer or a non-self-adhesive second layer, or over part of its surface area with a self-adhesive second layer or a non-self-adhesive second layer by adhesively bonding a self-adhesive or non-self-adhesive polymer-modified bitumen.

In a preferred embodiment of the invention, the object is also attained according to claim 5 in that the multilayer solar element includes the first layer of a photovoltaic thin layer laminate, which is coated on its bottom side with the second layer made of the polymer-modified bitumen, and which in addition is at least partially or completely adhesively cold-bonded or hot-bonded to a third, flexible or rigid layer (a support material).

In a preferred embodiment of the invention, the object is also attained in conjunction with the features of claims 1, 5 and 6 in that the multilayer solar element includes the first layer of the photovoltaic thin layer laminate, which is coated on its bottom side with a second layer of a polymer-modified bitumen and which is at least partially or completely adhesively cold-bonded or hot-bonded to the third, flexible or rigid layer (as a support material), which itself is then coated with at least one fourth layer of a polymer-modified bitumen.

In a preferred embodiment of the invention, the second and fourth layer are a self-adhesive bitumen layer of polymer-modified bitumen which is produced on the basis of SBS, SIS or APP and a tackifying resin. This second and fourth layer may be applied onto the corresponding layer (first and/or third layer) by so-called “cold bonding”, because a tackifying resin was added. It would also be feasible to “hot-bond” by heating the self-adhesive polymer-modified bitumen, thereby attaining an increased bonding strength (compared to cold-bonding). The type of adhesive bonding can be selected depending on the particular application and is already taken into consideration in the fabrication of the multilayer solar elements.

In a particular embodiment of the invention, the second and fourth layer are a non-self-adhesive bitumen layer of polymer-modified bitumen, which is produced on the basis of SBS, SIS or APP, however without a tackifying resin. In this embodiment, the first and/or third layer is coated with the second and/or fourth non-self-adhesive layer by “hot-bonding”, because the adhesive properties of bitumen are effective only after heating, i.e., because the self-adhesive properties of the bitumen are not present in the cold state due to the absence of the tackifying resin.

The invention provides an alternative for the structure of the multilayer solar elements, which is in a preferred embodiment taught in claims 2 to 4. In order to increase the permanent bond strength of the joint between the photovoltaic thin layer laminate (the first layer) and the polymer-modified bitumen layer (second self-adhesive or non-self-adhesive layer), which could be reduced by diffusion of plasticizers from the second polymer-modified bitumen layer into the first layer, the bottom side of the photovoltaic thin layer laminate is additionally provided with a barrier foil.

The barrier foil made of polyester is arranged on the bottom side of the first layer between the first and second layer as polyester barrier foil, which is adhesively bonded to the bottom side of the first layer with an adhesive, whereby the first layer is “laminated”.

In a preferred embodiment of the invention, the polyester barrier foil is a polyethylene terephthalate foil (PET foil), because it has been found that such polyester barrier foil is best suited to prevent plasticizers from diffusing from the polymer-modified second bitumen layer into the photovoltaic thin layer laminate.

In complex tests for producing a multilayer solar element, experiments were performed with the different adhesives and also with different barrier materials, and it was found that the photovoltaic thin layer laminate can be coated with polymer-modified bitumen (self-adhesive and non-self-adhesive type) to produce a multilayer, at least two-layer, solar element with excellent permanent peeling strength. It has been found with respect to permanence, that chemical processes, which reduce the permanence of the photovoltaic thin layer laminate (first layer) with the polymer-modified bitumen layer (second layer), can be countered effectively by arranging a polyester barrier foil. Fabrication without a barrier that is possible, the peeling strength is increased by using the second polymer-modified bitumen layer, and a high permanence is attained, however, the permanence is still further increased by using the barrier foil.

In a preferred embodiment of the invention, a melt adhesive or a polyurethane adhesive (PUR adhesive) or a reactive polyolefin adhesive (e.g., Si melt adhesive, supplied by the company Henkel) or a UV cross-linked adhesive are used for applying the polyester barrier foil.

Two possibilities exist for producing the joint between the first layer and the second layer.

In a first alternative, the polyester barrier layer is supplied in a coating apparatus to the photovoltaic thin-film laminate to be laminated via rollers. Depending on the barrier foil material, an optimal “lamination adhesive” is used, for example the aforementioned melt adhesive, a polyurethane adhesive (PUR adhesive), a reactive polyolefin adhesive (e.g., Si melt adhesive, supplied by the company Henkel) or a UV cross-linked adhesive.

Depending on the type of the adhesive, the lamination adhesive is, for example, sprayed through slotted nozzles onto the barrier foil. The polyester barrier foil with the adhesive is in the next step then adhesively bonded to or rolled on the backside of the modules. A photovoltaic thin layer laminate with a laminated polyester barrier foil is produced, which is preferably a polyethylene terephthalate foil (PET foil) or a polyethylene terephthalate foil (PET foil/Al/PET foil) with an interior aluminum layer.

For example, a polyester barrier foil with the name “Kemafoil” from the company Coverne can be used, which is preferably adhesively bonded to the backside of the photovoltaic thin layer laminate using one of the aforementioned types of adhesives.

For example, a biaxially stretched, co-extruded foil of a polyethylene terephthalate foil (PET foil) from the company Mitsubishi-Film with the name “Hostaphan RNK C” can be used, which is preferably adhesively bonded to the backside of the photovoltaic thin layer laminate with one of the aforementioned types of adhesive (e.g., Liofol from the company Henkel).

In a second alternative, the polyester barrier foil and the second polymer-modified bitumen layer are first conveyed to a coating facility. The two layers are first joined to a “barrier foil adhesive tape” composite using rollers.

In a self-adhesive second polymer-modified bitumen layer, unheated rollers may be sufficient for producing the barrier foil adhesive tape composite by “cold-bonding”. In a non-self-adhesive second polymer-modified bitumen layer, heated rollers are used which then produce the barrier foil adhesive tape composite by “hot-bonding”.

For producing the barrier foil-adhesive tape composite, the self-adhesive second polymer-modified bitumen layer can also be produced by “hot-bonding” using heated rollers, producing a barrier foil-adhesive tape composite with still higher bonding strength than can be obtained by “cold-bonding” with self-adhesive polymer-modified bitumen.

The barrier foil-adhesive tape composite produced in this way—the second layer with the applied polyester barrier foil, which is preferably a polyethylene terephthalate foil (PET foil)—is in adhesively bonded to the backside of the first layer (on the photovoltaic thin layer laminate) by using one of the aforementioned optimized “laminating adhesives”, depending on the type of barrier foil as described above. The laminating adhesive is then applied either on the bottom side of the first layer and/or on the side of the polyester barrier foil facing the first layer.

In this way, a composite of a photovoltaic thin layer laminate with a laminated polyester barrier foil is produced, which is preferably a polyethylene terephthalate foil (PET foil), and a second layer of a non-self-adhesive and/or a self-adhesive polymer-modified bitumen. This second layer represents a bonding layer to a base, for example a roof and the like, or the second layer may be provided with additional layers which will be described further in the dependent claims and in the specification.

Claims 14 and 15 teaches the use of a polymer-modified bitumen, in particular based on SBS, SIS or APP, for coating photovoltaic thin layer laminates, for producing multilayer solar elements with a first layer of the photovoltaic thin layer laminate and second, second and third, or second, third and fourth layers arranged on the thin layer laminate according to claims 1 to 13, whereby alternatively the use of a polyester barrier foil, which is preferably a polyethylene terephthalate foil (PET foil), is proposed, which is adhesively “laminated” on the bottom side of the photovoltaic thin layer laminate.

The approach for applying the polyester barrier foil on the photovoltaic thin layer laminate has already been described above.

For producing the multilayer solar element without a barrier foil, a method and an apparatus are used, wherein self-adhesive and non-self-adhesive polymer-modified bitumen is heated to a predetermined temperature in separate storage containers, and furthermore a first layer, a photovoltaic thin layer laminate, is conveyed by a transport arrangement to an outlet device, which is associated with the respective storage container and supplies the self-adhesive and/or non-self-adhesive polymer-modified bitumen, whereby a second self-adhesive layer, a non-self-adhesive layer or a self-adhesive layer with a non-adhesive layer is applied in the marginal region on the bottom side of the thin layer laminate. This basic process may be combined with the process for applying for barrier foil. The process steps and the required apparatuses will be described in more detail in the following description.

The invention will now be described with reference to the figures which each depict a cross-sectional view:

### Two-Layer Flexible Solar Elements:

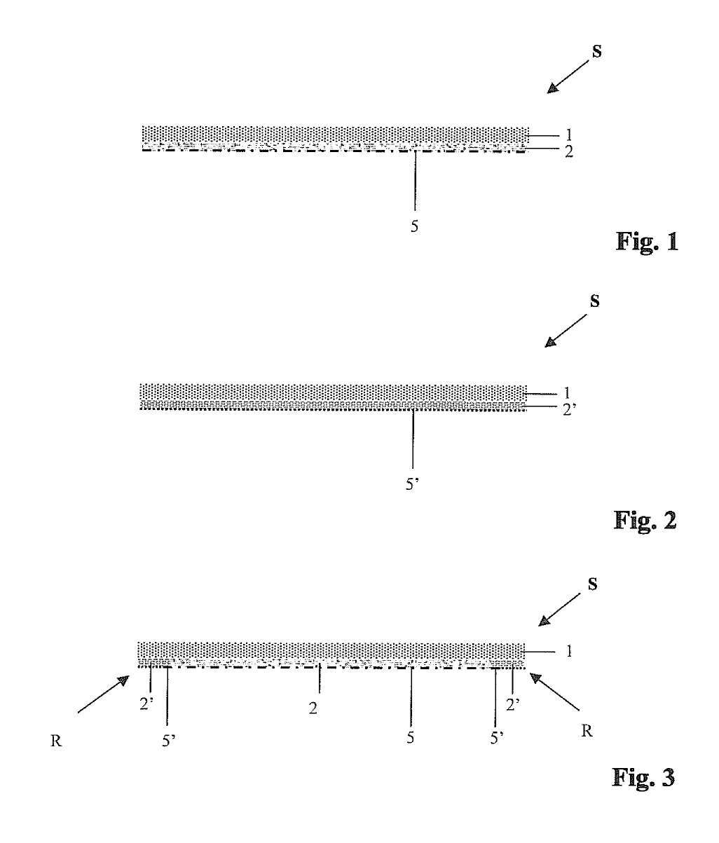

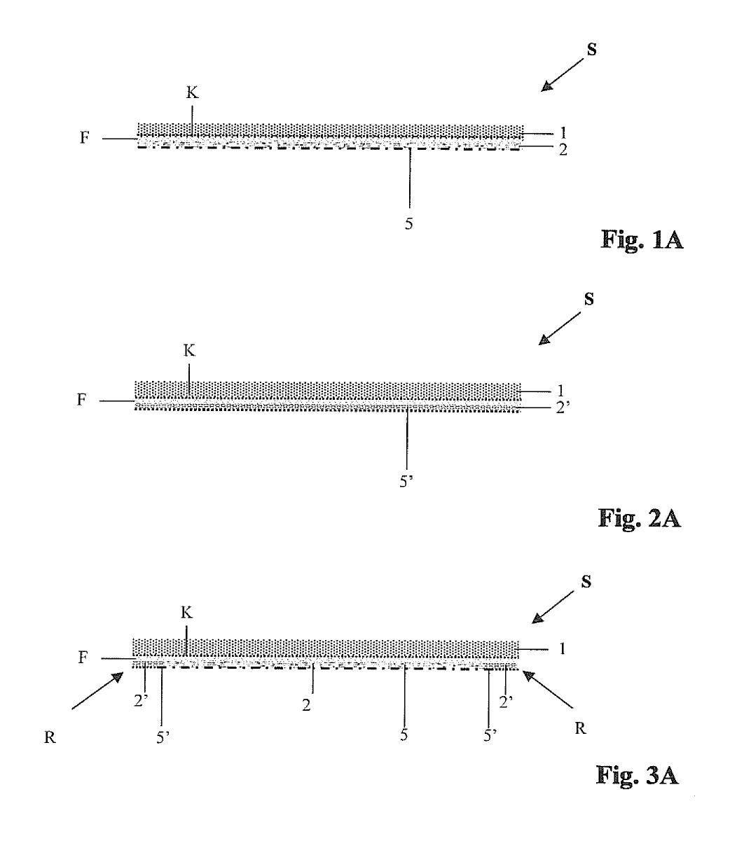

FIG. 1 a two-layer solar element, with a first photovoltaic thin layer and a full-surface, self-adhesive, second layer of a polymer-modified bitumen with protective barrier layer/barrier foil;

FIG. 2 a two-layer solar element, with a first photovoltaic thin layer and a full-surface, non-self-adhesive, second layer of a polymer-modified bitumen with protective barrier layer/barrier foil;

FIG. 3 a two-layer solar element, with a first photovoltaic thin layer and a self-adhesive second layer and a non-self-adhesive second layer in the marginal region of a solar element of polymer-modified bitumen with protective barrier layer/barrier foil;

### Three-Layer Flexible and Rigid Solar Elements:

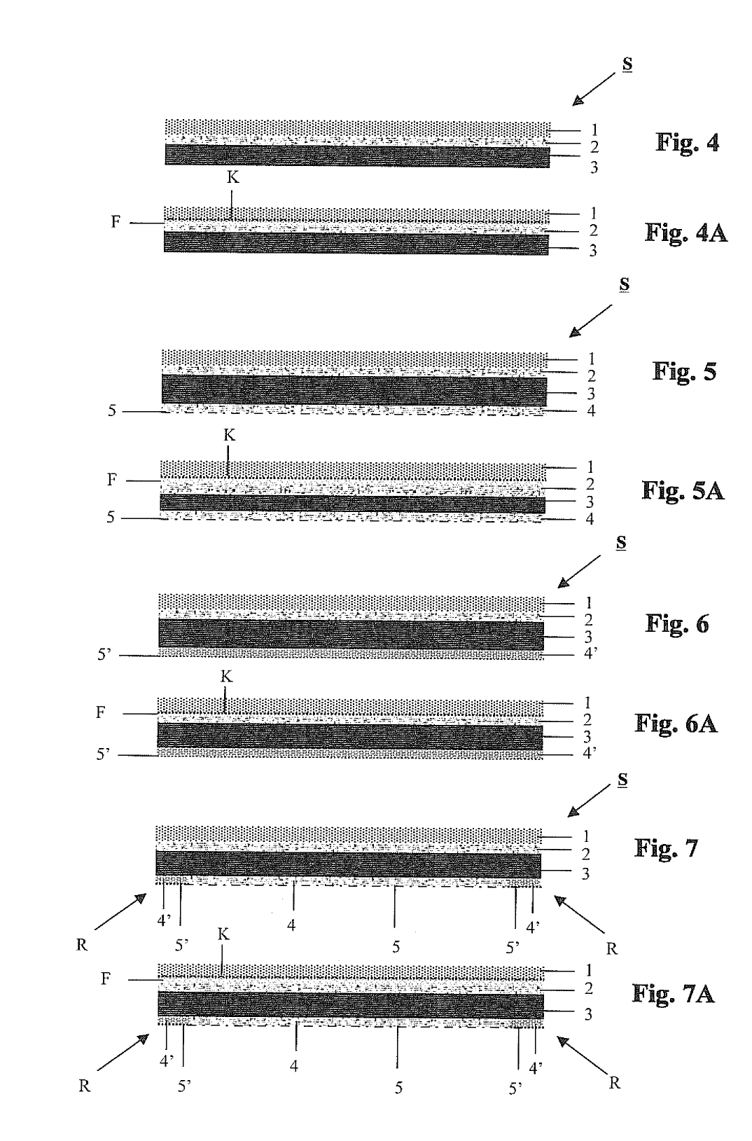

FIG. 4 a three-layer solar element, with a first photovoltaic thin layer and a full-surface, self-adhesive, second layer of a polymer-modified bitumen with a third layer made of a flexible or rigid support material;

### Four-Layer Flexible and Rigid Solar Elements:

FIG. 5 a four-layer solar element, with a first photovoltaic thin layer and a full-surface, self-adhesive, second layer of a polymer-modified bitumen and a third layer of a flexible or rigid support material and a full-surface, self-adhesive, fourth layer of a polymer-modified bitumen with protective barrier layer/barrier foil;

FIG. 6 a four-layer solar element, with a first photovoltaic thin layer and a full-surface, self-adhesive, second layer of a polymer-modified bitumen and a third layer of a flexible or rigid support material and a full-surface, non-self-adhesive, fourth layer of a polymer-modified bitumen with protective barrier layer/barrier foil;

FIG. 7 a four-layer solar element, with a first photovoltaic thin layer and a full-surface, self-adhesive, second layer of a polymer-modified bitumen and a third layer of a flexible or rigid support material and a non-self-adhesive, fourth layer in the marginal region of a solar element made of a polymer-modified bitumen with protective barrier layer/barrier foil;

Three-Layer and Four-Layer Flexible or Rigid Solar Elements with Overhang:

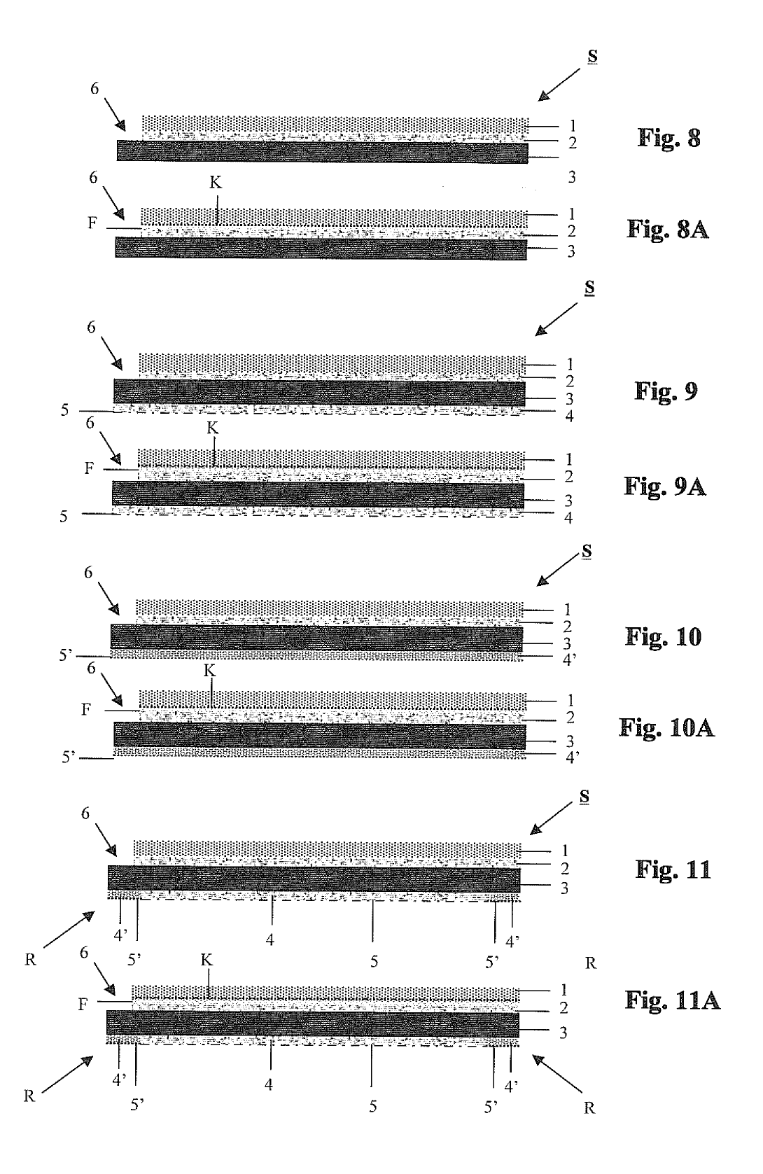

FIGS. 8-11 a solar element according to FIGS. 4 to 7 with one-sided overhang.

Multilayer Solar Elements According to FIGS. 1 to 11, However with a Polyester Barrier Foil:

FIGS. 1A to 11A a solar element according to FIGS. 1 to 11, however with a polyester barrier foil, which is arranged on the bottom side of the photovoltaic thin layer with an adhesive between the first photovoltaic thin layer and second self-adhesive or non-self-adhesive polymer-modified bitumen layer.

The abbreviations used in the context of the following description and the claims have the following meaning:

EPDM Ethylene propylene diene copolymer
IIR Butyl rubber
SBS Styrene Butadiene Styrene copolymer
SIS Styrene isoprene Styrene copolymer
APP Atactic polypropylene
TPE Thermoplastic elastomer

### PE Polyethylene

### PU Polyurethane

### E Polyester

PET Polyethylene terephthalate

### PP Polypropylene

### PA Polyamide

FIGS. 1 to 11 each show multilayer solar elements S, wherein the first layer 1 is always a photovoltaic thin layer laminate. These photovoltaic thin layer laminates have excellent energy conversion properties. They can be used in many applications at the high temperatures produced by the incident solar radiation as well as at lower temperatures and hence lower incident luminous intensity and have very good energy conversion efficiency. The photovoltaic thin-film laminates themselves also have a multilayer structure and are sold with a contacting plug and connector box already installed.

According to the state-of-the-art, these photovoltaic thin layer laminates are at present already adhesively attached to different support materials with butyl adhesive, whereby the employed support materials are typically roof sheeting strips, so that these products can be installed on or adhesively bonded to flat and sloped roofs. They can be used, for example, on sloped roofs from a minimum slope of 5° to a maximum slope of 60°.

It has been observed that in particular at high roof temperatures and increased roof slope, the adhesive joint produced with butyl adhesive is insufficient to reliably bond the layers to each other, so that the permanent bonding strength or peeling strength between the photovoltaic thin layer laminate and the support material is no longer guaranteed during prolonged heat exposure.

The following products (multilayer solar elements S) overcome this disadvantage in that the first layer 1 is coated with at least one second layer 2 of polymer-modified bitumen, forming an adhesive layer.

Other products are implemented by joining the first layer and the second layer 1, 2 of the photovoltaic thin layer laminate and the polymer-modified bitumen to a third layer 3, a support material.

Additional products can be implemented by coating the first, second and third layer 1, 2 and 3 made of the photovoltaic thin layer laminate, the polymer-modified bitumen and the support material with a fourth layer 4, 4′ made once more of polymer-modified bitumen as adhesive layer.

Modified embodiments of the multilayer solar elements S constructed in this way, but without barrier foil, will be described in more detail below, first with reference to the FIGS. 1 to 7 and then with reference to FIGS. 8 to 11.

The polymer-modified bitumen is here mixed with a tackifying resin to form a self-adhesive, polymer-modified bitumen layer, in particularly based on SBS, SIS or APP, and can additionally be mixed with a filler material. The bitumen fraction of the self-adhesive, polymer-modified bitumen layer is 50-75 wt.-%. However, a non-self adhesive, polymer-modified bitumen layer, in particular again based on SBS, SIS or APP, can be applied, to which no tackifying resin is admixed, but which can be again mixed with a filler material. The bitumen fraction is in this case 50-75 wt.-%.

It should be mentioned that the self-adhesive and non-self-adhesive polymer-modified bitumen layers 2, 2′ and 4, 4′ adhere, when heated, to the respective surfaces or bases and/or support materials. A self-adhesive polymer-modified bitumen layer 2, 4 has the additional characteristics that it is also self-adhesive when cold.

In the following description, the layers or barrier layers/barrier foils mentioned in conjunction with the non-self-adhesive, polymer-modified bitumen are indicated with an asterisk (′).

FIG. 1 shows a two-layer solar element S with a first layer 1 of a photovoltaic thin-film laminate which is coated with a self-adhesive, polymer-modified bitumen layer 2. An additional barrier foil 5 is applied to this second layer 2, which essentially protects and supports the two-layer solar element S. Due of the flexibility of the photovoltaic thin layer laminate, this two-layer solar element S represents a kind of universally employable, flexible solar element S in mostly rectangular strip form. When installing the multilayer solar element S according to FIG. 1, a full-surface, a strip-wise, or a point-like adhesive joined with a base may be formed, in that the second self-adhesive layer 2 is intrinsically applied on the thin layer laminate 1 in this manner. This second self-adhesive, polymer-modified bitumen layer 2′ is applied by cold-bonding or hot-bonding. Cold-bonding is possible because the self-adhesive, polymer-modified bitumen layer 2 can also be adhesively bonded in the cold state because of the tackifying resin.

FIG. 2 shows, similar to FIG. 1, a two-layer solar element S which also represents a kind of universally usable, flexible solar element S, wherein the first layer (1) is coated with second layer 2′ of non-self-adhesive, polymer-modified bitumen. This second non-self-adhesive, polymer-modified bitumen layer 2′ is applied by hot-bonding. Essentially for the purpose of securing and support, a barrier foil 5′ is once more applied on a second non-self-adhesive layer 2′.

The barrier foils 5 and 5′ may be produced as barrier layers made from PE, PP, TA, E, or PU material.

The barrier layer 5 has, in relation to the self-adhesive bitumen coating of the second and fourth layer 2, 4, a thickness of 60 μm to 100 μm, whereas the barrier layer 5′ has, in relation to the non-self-adhesive bitumen coating of the second and fourth layer 2′, 4′ a thickness of 5 μm to 20 μm.

The respective associated barrier layers 5, 5′ may be colored differently.

In another embodiment, the self-adhesive bitumen coatings of the second and fourth layer 2, 4 and the non-self-adhesive bitumen coating of the second and fourth layer 2′, 4′ are provided with a coat of fine quartz in the of and associated barrier foil 5, 5′ as barrier layer.

Because of the existing flexibility, the two-layer non-self-adhesive solar element S of FIG. 2 is also a type of solar strip which, however, cannot be adhesively bonded, like the two-layer solar element S of FIG. 1, immediately after the foil 5 is pulled off, but such solar strip is installed instead, for example on a roof by applying an adhesive on the roof, as a full-surface adhesive joint with contact adhesive, hot bitumen, or polymer-modified bitumen, or strip-wise adhesive joint, also with contact adhesive, hot bitumen, or polymer-modified bitumen. To this end, this two-layer solar element S can be adhesively bonded to the roof by first pulling off the barrier foil 5′.

If the solar element S is mechanically attached according to FIG. 2, a barrier foil 5′ remaining on the first layer 1 operates also as a vapor barrier or vapor retardant and prevents moisture from entering in the direction of the first layer 1, the photovoltaic thin layer laminate.

The second layer 2′ can also be implemented across a partial surface area, here in particular in form of strips, or across the full surface area.

Several solar elements S according to FIG. 2 can be installed directly over the full surface area the roof in an abutting configuration by hot-air welding.

Due to its self-adhesive properties, the two-layer solar element S according to FIG. 1 can be adhesively bonded to a roof without the use of additional adhesive or process steps, such as hot-air welding. The two-layer solar element S of FIG. 1 can also be installed on a roof or the like, as described with reference to FIG. 2.

FIG. 3 shows an additional, two-layer solar element S, which has once more the first layer 1 with a photovoltaic thin layer laminate and a second layer 2, 2′, wherein the marginal regions R are coated with a second layer 2′ of non-self-adhesive, polymer-modified bitumen. The illustration of FIG. 3 shows a left and a right margin region R, wherein the depicted cross-section does not show the front edge and the rear edge of a rectangular multilayer solar element S, which may also have such a marginal region R. In such multilayer solar elements S having marginal regions R, at least one edge R, opposing edges R or all edges R may be coated with non-self-adhesive, polymer-modified bitumen 2′.

The illustrated central region is coated with self-adhesive polymer-modified bitumen 2, wherein different a barrier foils 5, 5′ are arranged on the second layer 2, 2′. It is contemplated that the barrier foil 5 slightly overlaps the barrier foil 5′.

When installing this likewise flexible solar strip S having at least one marginal region R, this solar element S is rolled out, for example, on a roof surface, while the barrier foil 5 is simultaneously pulled off, so that the self-adhesive, second layer 2 is exposed and is adhesively bonded to the roof. The barrier foil 5′ remains in the marginal region R on the second marginal layers 2′ and can be connected with other flexible or non-flexible solar strips in overlapping relationship by hot-air welding (whereby the barrier foil 5′ dissolves) by sealing the layers with one another and hence also sealing the roof. With this installation, full-surface, strip-wise or point-wise adhesive bonding can be performed, by applying the second, self-adhesive layer 2 on the photovoltaic thin layer laminate 1 from the beginning, meaning already during fabrication. If a full-surface, a strip-wise or a point-wise installation is performed depends on the respective roof base.

In summary, the FIGS. 1 to 3 show flexible solar strips as solar elements S with a first layer 1 of a photovoltaic thin layer laminate, which is coated either with self-adhesive bitumen 2, non-self-adhesive bitumen 2′, or a combination thereof within the second layer 2, 2′, wherein the respective barrier foils 5, 5′ are either present or can be pulled off to provide protection during storage or processing.

FIG. 4 shows a three-layer solar element S, which has a first layer 1 once more made of photovoltaic thin layer laminate, and a second layer 2 made of self-adhesive, polymer-modified bitumen, wherein a support material is cold-bonded or hot-bonded on this second layer 2 to form a third layer 3. The support material 3 can be a sheet-metal material having different thickness, so that depending on the flexibility of the sheet-metal used in support material, three-layer flexible solar strips or, if the employed sheet metal has greater stiffness, universally applicable, three-layer rigid solar panels are produced.

The third layer 3 can also be implemented with sealing strips, which can typically be obtained as a multilayer finished product. The sealing strips may also be cold-bonded or hot-bonded to the self-adhesive, polymer-modified second bitumen layer 2, wherein again flexible solar strips 1, 2, 3 or three-layer flexible (with greater stiffness, so-called “rigid”) solar panels 1, 2, 3 can be produced depending on this stiffness of the sealing strips three-layer.

The three-layer solar elements S coated with sheet-metal or the sealing strips are typically designed for mechanical attachment so that the respective third layer 3 has, for mechanical attachment of the solar elements S, a predetermined overhang 6 with respect to the existing first and second layer 1, 2. These modified embodiments are illustrated in FIGS. 8 to 11 and will be described later in more detail.

When the sealing strips are cold-bonded or hot-bonded with self-adhesive, polymer-modified bitumen as a second layer 2 to the third layer 3 arranged on the second layer, then the installation on the roof involves applying on the roof contact adhesive, hot bitumen or polymer-modified bitumen and adhesively bonding over the full surface area, strip-wise or point-wise. This type of installation can also be used with the three-layer solar elements S coated with sheet-metal, with the selection depending on the respective roof base.

Several solar elements according to FIG. 4, where the third layer 3 has a sealing strip as support material, can also be installed across the full surface area of the roof by abutting the solar elements S and hot-air welding. Installation with a defined overhang 6 is illustrated and described with reference to FIGS. 8 to 11.

FIG. 5 shows the three-layer solar element S described in FIG. 4 in a four-layer embodiment, wherein once more self-adhesive, polymer-modified bitumen is deposited first as the fourth layer 4, on which again a barrier foil 5 is arranged. This fourth self-adhesive, polymer-modified bitumen layer 5 is also deposited onto the third layer 3, as shown in FIG. 6, by cold-bonding or hot-bonding. Cold-bonding is feasible in addition to or instead of hot-bonding because this is a self-adhesive material.

FIG. 6 shows similarly a four-layer solar element S, wherein the fourth layer 4′ is made of non-self-adhesive, polymer-modified bitumen, with the barrier foil 5′ being arranged as barrier layer. This non-self-adhesive, polymer-modified bitumen layer 4′ is deposited on the third layer 3 in FIG. 6 by hot-bonding, because this is a non-self-adhesive material.

The four-layer solar element S depicted in FIG. 5 can once more be easily placed on a roof, after the barrier foil 5 is pulled off, and be cold-bonded to the base due to the self-adhesive properties of the fourth layer 4. In this installation, a full-surface, a strip-wise or a point-wise adhesive bonding can be implemented by depositing the fourth self-adhesive layer 4 onto the third layer 3, the support material, initially during manufacture. The selection depends also here again on the respective roof base.

For the third layer 3 in FIG. 5, a rigid or flexible sheet metal can once more be used as support material, or a flexible or rigid sealing strip can be used as support material. Depending on the flexibility of the support material layer 3, four-layer solar elements S are produced as self-adhesive flexible solar strips or self-adhesive rigid solar panels.

If according to FIG. 5 a mechanical attachment is provided for the solar elements S in addition to adhesive bonding, then the third layer 3 is again preferably produced with a corresponding overhang 6 with respect to the first and second layer or the fourth layer 4 according to FIG. 9, so that an additional mechanical attachment of the solar panel or of the solar strip on the roofs can be realized.

Likewise, four-layer non-self-adhesive solar elements S are obtained as non-self-adhesive solar panels or solar strips, with the following alternatives for attachment.

If a mechanical attachment is provided, then the third layer 3 is once more produced with a corresponding overhang 6 with respect to the first and second layer or the fourth layer 4′ according to FIG. 10, so that a mechanical attachment of the solar panel or of the solar strip on the roofs can be realized.

With a mechanical attachment of the solar element S in accordance with FIG. 6 or 10, the barrier foil 5′ operates again as vapor barrier or vapor retardant and prevents moisture from entering in the direction of the first layer 1, the photovoltaic thin layer laminate.

Several solar elements S according to FIGS. 5 and 6, wherein the third layer is implemented as a sealing strip as a support material, can also be installed directly on the roof over the full surface area or over a partial surface area in an abutting relationship by hot-air welding. The respective foil 5, 5′ dissolves when the solar elements S are exposed to hot air in the abutting region.

On the other hand, adhesive bonding on the roof is possible by pulling off the barrier foil 5, 5′. According to FIG. 5, the solar elements S adhere automatically after the barrier foil 5 is pulled off, as described above.

After the barrier foil 5′ has been pulled off, the four-layer non-self-adhesive solar elements S and non-self-adhesive solar panels or solar strips are installed by applying an adhesive on the roof as a full-surface adhesive bond with contact adhesive, hot bitumen, polymer-modified bitumen, or a strip-wise adhesive bond with contact adhesive, hot bitumen, or polymer-modified bitumen. The selection for the installation depends again on the roof base.

FIG. 7 shows, similar to FIG. 3, a four-layer solar element S with a coating of non-self-adhesive, polymer-modified bitumen 4′ in the marginal regions R of the fourth layer 4. Otherwise, the fourth layer 4 is again coated with self-adhesive, polymer-modified bitumen, wherein the third layer 3 made of flexible or rigid sheet-metal or flexible or rigid sealing strips is again cold-bonded or hot-bonded, as already described with reference to FIGS. 4 to 6, to the first layer 1, the photovoltaic thin layer laminate, via the second layer 2 made of self-adhesive, polymer-modified bitumen 2.

In the embodiment of FIG. 7, the self-adhesive, fourth layer 4 can advantageously be adhesively bonded to the roof after the barrier foil 5 is pulled off, without having to apply a separate adhesive and the like on the roof. The marginal regions R remain coated with the barrier foils 5′ when the barrier layer 5 is pulled off, because the barrier foil 5 remains on the non-self-adhesive, fourth edges R of the fourth layer 4′, when the barrier foil 5 which is arranged in overlapping relationship with the barrier foil 5′ is pulled off. In this way, the edges remain exposed and do initially not bond.

This approach can be used when installing the solar elements S. The barrier layer 5 is pulled off from the self-adhesive bitumen coating of the second and fourth layer 2, 4 before installation, whereas the barrier layer 5′ forms a fixed bond with the non-self adhesive bitumen coating of the second and fourth layer 2′, 4′.

In the marginal regions R, several multilayer solar elements S which overlap in the marginal regions R can then again be welded with hot air. The barrier foil 5′ can here remain on the bottom side of the solar element S. This barrier foil 5′ is comparatively thinner and is dissolved by the heat during hot-air welding with hot air. The layers joined in this way are then bonded to each other by heating with hot air, the so-called hot-air welding.

The four-layer solar elements S of FIG. 7 can also be self-adhesively installed over the full surface area, strip-wise or point-wise by initially depositing the first self-adhesive layer 4 on the third layer 3, the support material. The selection of the fourth layer, self-adhesive 4, non-self-adhesive 4′ or a combination thereof, depends again on the respective roof base.

Preferably, sheet-metal according to DIN EN 10326/143 with a minimum size of S250GD with a coating AZ185 is proposed for the flexible or rigid sheet-metal, which can be used in FIGS. 4 to 11 as the third layer 3.

In another embodiment of according to FIGS. 4 to 11, a multilayer sealing strip, which has a first, upper layer as a patterned or unpatterned TPE layer, and a second layer, as an EPDM layer with integrated glass fabric, and a third layer as TPE layer, is proposed as flexible or optionally rigid sealing strips for the third layer 3.

The non-self-adhesive and/or self-adhesive, polymer-modified bitumen layers 2, 2′ exhibit excellent peeling strength relative to the first layer 1, the photovoltaic thin layer laminate, wherein this value is 7× to 8× higher than the required minimum value of ≧1.0 N/mm².

Advantageously, this 7× to 8× higher value could be confirmed, in particular in the adhesively bonded, as well as in the welded forms where a joint to a support material 3 is produced at a later stage.

In FIGS. 1, 2, 3 as well as 5, 6, 7 and 9, 10, 11, adhesive bonding with the respective base is typically accomplished with 7- to 8-times higher bonding strength values. These values are otherwise attained only in products which are hot-air welded to the base.

The two-layer solar elements S described with reference to FIGS. 1, 2 and 3 may be applied together on support layers 3, such as uncoated or coated metals, plastics (with the exception of soft PVC, which are monomer-softened) or bitumen sealing strips or other types of sealing strips.

The aforedescribed bitumen strips which can be used as a sealing strips and form the third layer 3 and which themselves are already implemented as multilayers, form a joint with the photovoltaic thin layer laminate, the first layer 1, for example by way of a self-adhesive, polymer-modified bitumen layer 2, with high cohesion and adhesion. This excludes, as already mentioned, the monomer-softened PVC roofing strips.

The products according to FIGS. 2, 3, 6 and 7 as well as 10 and 11, which each have non-self-adhesive layers 2′, 4′ or non-self-adhesive regions, exhibit excellent hot-air weldability in these layers 2′, 4′.

Self-adhesive layers 2, 4 can be, as described above, also hot-air welded with excellent results, however, hot air welding is typically not necessary because of their self-adhesive properties. Optionally, the aforedescribed abutting hot-air welding is performed in addition to the self-adhesive properties.

Are multilayer solar elements S have excellent stability, in particular at high temperatures, and excellent permanent compatibility with a large variety of support materials 3 (roofing materials).

In full-surface adhesive bonding of the multilayer solar elements S on the existing roofing strip, with the exception of marginal regions R, for example with the solar elements S according to FIGS. 1, 3, 5, 7, 9 and 11 as a result of the already applied self-adhesive polymer-modified layer 4, corresponding primers should be applied.

The three-layer and four-layer solar elements S according to FIGS. 8, 9, 10 and 11, which are coated with sheet-metal or sealing strips, are constructed with at least one overhang 6 for possible mechanical attachment or for hot-air welding along the edges. This overhang 6 may be provided on opposing edges or on all edges or, for example, across the corners. A one-sided embodiment is illustrated in the respective cross-sectional views of FIGS. 8, 9, 10 and 11.

As already described above, the layers 3, 4 or 3′, 4′ may be attached to the roof only mechanically, or the lower layer is, for example, mechanically attached, whereas the upper layer which overlaps in the marginal region 6 is adhesively bonded to the lower layer.

In another embodiment, the overlapping adhesive bonding in the marginal region R by way of the respective overlap 6 is accomplished entirely without mechanical attachment. This will be briefly described below with reference to FIGS. 8, 9, 10 and 11.

A solar element S according to FIG. 8 may preferably be a sheet-metal as third support material layer 3 which is only mechanically attached with a one-sided or two-sided overlap 6.

In FIG. 10, the first, self-adhesive polymer-modified bitumen layer 4 is applied to the third layer 3 by cold-bonding or hot-bonding, i.e., the first layer 4 is applied in a cold or hot state of the polymer-modified bitumen, with the hot bitumen then cooling down again after application.

FIG. 9 enables a preferably one-sided, two-sided or peripherally overlapping, self-adhesive installation on a roof with overlap 6, by way of the self-adhesive, polymer-modified bitumen layer 4. Additional hot-air welding in the overlapping region (in the overlap 6) is feasible.

In FIG. 10, the fourth, non-self-adhesive, polymer-modified bitumen layer 4′ is applied on the third layer 3 by hot-bonding, i.e., the fourth layer 4′ is applied in a hot state of the polymer-modified bitumen, which thereafter cools down again.

A solar element S according to FIG. 10 can be arranged, in addition to the installation options described with reference to FIG. 6, by installing several solar elements S, where the third layer 3 is a sealing strip as support material, directly on the roof across the full surface area not in an abutting relationship, but with an overlap 6, by way of hot-air welding. When the solar element S is mechanically attached of by way of the overlap 6, the barrier foil 5′ in FIG. 10 operates as a vapor barrier and prevents moisture from entering in the direction of the first layer 1, the photovoltaic thin layer laminate. The barrier foil 5′ is dissolved in the region of the overlap 6 during optional hot-air welding.

FIG. 11 also shows the overlap 6 used for overlapping installation of the four-layer solar element S, as already described with reference to FIG. 7. The overlap 6 can also be used in the additional optional mechanical attachment.

The two-layer solar elements S without a polyester barrier foil disposed between the first and the second layer are produced as follows. Self-adhesive and non-self-adhesive, polymer-modified bitumen is heated in separate storage containers to a predetermined temperature, so that the bitumen is free-flowing.

The first layer 1, the photovoltaic thin layer laminate, is then conveyed via a transport device to the respective storage container so that self-adhesive and/or non-self-adhesive, polymer-modified bitumen can be supplied in form of layers to the bottom side of the thin layer laminate. With this approach, the two-layer solar elements S according to FIGS. 1, 2, 3 are produced, wherein in the embodiment of FIG. 3, non-self-adhesive, polymer-modified bitumen is supplied only in the marginal region R.

During deposition of the second layer 2, 2′, the photovoltaic thin layer laminate 1 is cooled in the region where the polymer-modified bitumen is deposited on the top side and/or bottom side with a cooling device.

The transport device is constructed so that the thin layer laminate equipped with plugs and connector boxes can be easily routed along the respective storage container, without damaging the provided connections.

In addition, the already deposited, second layers 2, 2′ may be cooled also in the subsequent region of the top side and bottom side, so that the deposited layers 2, 2′ can be flattened in an additional step with an annealing device at a predetermined temperature.

Preferably after flattening, the aforedescribed barrier layers 5, 5′ are applied, which are made of a foil material and conveyed via a first feed device and placed on the respective layer 2, 2′. Subsequently, further processing takes place to produce a three-layer or multilayer solar element S in a continuous or discontinuous deposition process. Depending on the type of the solar element S, its size or intended installation, the third layer 3 and/or the fourth layer 4 with the corresponding barrier layers 5, 5′ with the two-layer solar element S according to FIGS. 1 to 3 are cold-bonded or hot-bonded to the support layer 3, and optionally to fourth self-adhesive or non-self-adhesive layers 4, 4′ attached thereto, using polymer-modified, self-adhesive or non-self-adhesive bitumen.

FIGS. 1A to 11A show the multilayer solar elements S according to FIGS. 1 to 11, which however have each a polyester barrier foil F, which is arranged with an adhesive K on the bottom side of the photovoltaic thin layer 1 between the first photovoltaic thin layer 1 and the second self-adhesive or non-self-adhesive layer 2, 2′.

The description of the FIGS. 1 to 11 also applies to the FIGS. 1A to 11A, whereby in addition to the aforedescribed process a polyester barrier foil F is “laminated” to the first layer 1, the first photovoltaic thin layer laminate.

High-quality multilayer solar elements S are produced, which—as shown in FIGS. 1A and 2A—are produced as two layers 1, 2 or 1, 2′ from a first layer made of photovoltaic thin layer laminate 1 and a second full-surface, self-adhesive or non-self-adhesive layer 2, 2′ and a respective full-surface barrier layer 5, 5′.

The self-adhesive polymer-modified bitumen layer 2 (see FIG. 1A) is hereby pressed or rolled against the polyester barrier foil F using cold or heated rollers, and is connectable by cold-bonding or hot-bonding to the second layer 2, wherein the second layer 2 with the barrier foil is adhesively bonded to the bottom side of the first layer 1, the photovoltaic thin layer laminate, with an adhesive K.

The non-self-adhesive, polymer-modified bitumen layer 2 (FIG. 1A) is hereby pressed or rolled against the polyester barrier foil F using heated rollers, and is connectable by hot-bonding to the second layer 2, wherein the second layer 2 with the barrier foil is adhesively bonded to the bottom side of the first layer 1, the photovoltaic thin layer laminate, with an adhesive K.

The multilayer solar element S of FIG. 3A is produced in a similar manner; however, the central region is coated with self-adhesive, polymer-modified bitumen 2, whereas the marginal regions R of the second layer 2′ are coated with non-self-adhesive, polymer-modified bitumen by hot-bonding. The significance of the marginal region R for installation of the solar element on a base and this type of coating were already described in conjunction with FIG. 3.

In summary, FIGS. 1A, 2A and 3A show flexible solar strips as solar elements S, with a first layer 1 of a photovoltaic thin layer laminate and a laminated polyester barrier foil F, in particular a polyethylene terephthalate foil (PET foil), or a polyethylene terephthalate/aluminum/polyethylene terephthalate foil (PET/Al/PET foil), which is coated either with self-adhesive bitumen 2, non-self-adhesive bitumen 2′, or a combination thereof, within the second layer 2, 2′, whereby the respective barrier foils 5, 5′ are provided for protection, storage and future processing or installation on a base.

FIGS. 4A to 11A show the multilayer solar elements S in other embodiments according to the description of the FIGS. 4 to 11, however this time with a laminated polyester barrier foil F, in particular a polyethylene terephthalate foil (PET foil) or a polyethylene terephthalate/aluminum/polyethylene terephthalate foil (PET/Al/PET foil), for protecting the photovoltaic thin layer laminate 1 against chemical effects from the second self-adhesive and/or non-self-adhesive, polymer-modified bitumen layer 2, 2′.

Depending on the application, the user can select from a large number of multilayer solar elements S according to FIGS. 1 to 11 (without a polyester barrier foil F) and FIGS. 1A to 11A (with a polyester barrier foil F), with the description of FIGS. 1 to 11 regarding the installation options on a base, in particular a roof, applying likewise for the solar elements of FIGS. 1A to 11A. The invention proposes the use of a polymer-modified bitumen adhesive, in particular on the basis of the SBS, SIS or APP, for coating photovoltaic thin layer laminates in the production of a multilayer solar element S, with a first layer 1 of a photovoltaic thin layer laminate, which is alternatively laminated on its bottom side with a polyester barrier foil (F), which is preferably a polyethylene terephthalate foil (PET foil, by using an adhesive (K).

Such solar element S has, for example, two layers 1, 2/1, 2′/1, 2, 2′ or three layers 1, 2, 3 or four layers 1, 2, 3, 4/1, 2, 3, 4′/1, 2, 3, 4, 4′.

In one embodiment, the second and fourth layer are formed as a self-adhesive bitumen layer 2, 4 or a non-self-adhesive bitumen layer 2′, 4′.

In another embodiment, the second and/or fourth bitumen layers are formed as self-adhesive or non-self-adhesive bitumen layers 2, 2′/4, 4′.

### LIST OF REFERENCES SYMBOLS

S Multilayer solar element
1 First layer (photovoltaic thin layer)
K Adhesive
F Barrier foil
2 Second layer [polymer-modified bitumen (self-adhesive)]
2′ Second layer [polymer-modified bitumen (non-self-adhesive)]
3 Third layer [support material layer]
4 Fourth layer [polymer-modified bitumen (self-adhesive)]
4′ Fourth layer [polymer-modified bitumen (non-self-adhesive)]
5 Barrier foil on polymer-modified bitumen (self-adhesive)
5′ Barrier foil on polymer-modified bitumen (non-self-adhesive)
6 Overhang
R Marginal region

1-25. (canceled)

26. Multilayer solar element (S), comprising a first layer (1) of a photovoltaic thin layer laminate, which is coated on its bottom side as a bonding layer to a base or to a support material over its full surface area with a self-adhesive second layer (2) or a non-self-adhesive second layer (2′), or over part of its surface area with a self-adhesive second layer (2) or a non-self-adhesive second layer (2′) by adhesively bonding a self-adhesive or non-self-adhesive polymer-modified bitumen.

27. Multilayer solar element according to claim 26, wherein a polyester barrier foil (F), which is joined—“laminated”—with the first layer (1), is arranged on the bottom side of the first layer (1) between the first and second layer (1, 2, 2′).

28. Multilayer solar element according to claim 27, wherein the polyester barrier foil (F) is a polyethylene terephthalate foil (PET foil), or a polyethylene terephthalate/aluminum/polyethylene terephthalate foil (PET/Al/PET foil) with an interior aluminum layer.

29. Multilayer solar element according to claim 27, wherein the adhesive (K) is a melt adhesive, a polyurethane adhesive (PUR adhesive) or a reactive polyolefin adhesive (Si melt) or a UV cross-linked adhesive.

30. Multilayer solar element according to claim 26, wherein the respective second layer (2, 2′) is on its bottom side at least partially adhesively bonded with a third, flexible or rigid layer (3) as support material.

31. Multilayer solar element according to claim 30, wherein the third flexible or rigid layer (3) as support material is coated with a fourth layer (4, 4′) made of a polymer-modified bitumen adhesive.

32. Multilayer solar element according to claim 31, wherein the fourth layer (4, 4′) is formed over part of a surface area or over the full surface area.

33. Multilayer solar element according to claim 26, wherein the second or fourth layer (2, 2′, 4, 4′) is formed over part of a surface area as a strip-wise coating.

34. Multilayer solar element according to claim 26, wherein the second and fourth layer (2, 4) as self-adhesive bitumen layer and the second and fourth layer (2, 4) as non-self-adhesive bitumen layer is a polymer-modified bitumen adhesive, which is produced on the basis of SBS, SIS or APP, and which either comprises a tackifying resin or does not comprise a tackifying resin.

35. Multilayer solar element according to claim 26, wherein the second and fourth layer (2, 4) are self-adhesive bitumen layers, that however the second and fourth layer (2′, 4′) comprise marginal regions (R) with a non-self-adhesive bitumen layer.

36. Multilayer solar element according to claim 34, wherein the self-adhesive bitumen layer of the second and fourth layer (2, 4) and the non-self-adhesive bitumen coating of the second and fourth layer (2′, 4′) are each provided with an associated barrier layer (5, 5′) having a different thickness.

37. Multilayer solar element according to claim 36, wherein that the barrier layer (5, 5′) is a foil, in particular a PE, PP, PA, E or PU foil.

38. Multilayer solar element according to claim 30, wherein that the support material as the third flexible or rigid layer (3) is a sealing strip which can be adhesively bonded to the second self-adhesive layer (2).

39. Method for coating a layer of a photovoltaic laminate, comprising: using a self-adhesive or non-self-adhesive polymer-modified bitumen adhesive on the basis of styrene butadiene styrene copolymer (SBS), styrene isoprene styrene copolymer (SIS) or atactic polypropylene (APP), coating a bottom side of a first layer (1) comprising a photovoltaic thin layer laminate of a multilayer solar element (S) with a self-adhesive second layer (2) and/or a non-self-adhesive second layer (2′) by adhesively bonding the polymer-modified bitumen adhesive, as a bonding layer to a base or to a support material.

40. Method according to claim 39, on the basis of styrene butadiene styrene copolymer (SBS), styrene isoprene styrene copolymer (SIS) or atactic polypropylene (APP), for coating the third layer (3), which comprises a support material, with a self-adhesive second layer (2) and/or a non-self-adhesive second layer (2′) by adhesively bonding the polymer-modified bitumen adhesive, as a bonding layer to a base.
